(19) United States
(12) Patent Application Publication
(10) Pub. No.: US 2025/0357238 A1
(43) Pub. Date: Nov. 20, 2025

(54) PACKAGE INCLUDING SUBSTRATES, INTEGRATED DEVICES, AND HEAT SLUG

(71) Applicant: QUALCOMM Incorporated, San Diego, CA (US)

(72) Inventors: Rajneesh KUMAR, San Diego, CA (US); Manuel ALDRETE, Encinitas, CA (US); Piyush GUPTA, San Diego, CA (US); Bohan YAN, San Diego, CA (US); Aniket PATIL, San Diego, CA (US)

(21) Appl. No.: 18/667,049

(22) Filed: May 17, 2024

(51) Int. Cl. H01L 23/367; H01L 21/48; H01L 23/00; H01L 25/10

(52) U.S. Cl. CPC H01L 23/367; H01L 21/4882; H01L 25/105; H01L 24/16; H01L 24/32; H01L 24/73; H01L 2224/16225; H01L 2224/32225; H01L 2224/73204; H01L 2224/73253; H01L 2225/1023; H01L 2924/1815

(57) ABSTRACT

A device includes a first integrated device coupled to a first substrate and a second integrated device coupled to a second substrate. The first substrate is disposed between the first integrated device and the second integrated device. The first integrated device is electrically connected to the second integrated device. The device also includes a heat slug defining protrusions. The protrusions are thermally coupled, via contacts of the first substrate, to the second integrated device.

### FIELD

Various features relate to packages with substrates, integrated devices and a heat slug.

### DESCRIPTION OF RELATED ART

In the context of integrated circuit (IC) packaging, a “packaged IC device” (or simply a “package”) refers to an arrangement of one or more IC devices with additional components that facilitate operation of the IC devices. For example, the additional components retain and protect the IC devices. The additional components often electrically connect the IC devices to one another and include off-package contact to enable the packaged IC device to be connected to other circuits or devices. The IC devices and components coupled together in a package can be configured to perform various electrical functions.

There is an ongoing demand for improved packages. For example, many package improvements focus on goals such as reducing the dimensions of the package, increasing the performance of the package or the IC devices therein, increasing the efficiency of the package or the IC devices, reducing the cost of the package or the IC devices therein, or combinations of the above. Unfortunately, it is often the case that improvements to one of these goals comes at the cost of one or more of the others. For example, reducing package size can exacerbate heat dissipation concerns, which can lead to performance throttling to limit heat generation.

### SUMMARY

Various features relate to integrated circuit devices.

One example provides a device that includes a first integrated device coupled to a first substrate and a second integrated device coupled to a second substrate, where the first substrate is disposed between the first integrated device and the second integrated device and the first integrated device is electrically connected to the second integrated device. The device also includes a heat slug defining protrusions. The protrusions are thermally coupled, via contacts of the first substrate, to the second integrated device.

Another example provides a method of fabrication that includes coupling a heat slug and a first integrated device to a first substrate of an assembly. The assembly includes the first substrate, a second substrate, and a second integrated device coupled to the second substrate disposed between the first substrate and the second substrate. Coupling the first integrated device to the first substrate electrically connects the first integrated device and the second integrated device, and coupling the heat slug to the first substrate thermally couples the heat slug and the second integrated device. The method also includes, after coupling the heat slug to the first substrate, applying an underfill material between the heat slug and the first substrate in a region between protrusions of the heat slug.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a schematic cross sectional profile view of a package that includes multiple integrated devices and at least one heat slug.

FIG. 2 illustrates a schematic cross sectional profile view of a package that includes multiple integrated devices and at least one heat slug.

FIG. 3 illustrates a schematic cross sectional profile view of a package that includes multiple integrated devices and at least one heat slug.

FIG. 4 illustrates a schematic cross sectional profile view of a package that includes multiple integrated devices and at least one heat slug.

FIG. 5A illustrates a schematic bottom view of a heat slug of any of FIGS. 1-4.

FIG. 5B illustrates a schematic top view of a substrate of a package configured to couple to the heat slug of FIG. 5A.

FIG. 6 illustrates a schematic top view of a package that includes multiple integrated devices and at least one heat slug.

FIG. 7 illustrates a schematic top view of a package that includes multiple integrated devices and at least one heat slug.

FIG. 8 illustrates a schematic top view of a package that includes multiple integrated devices and at least one heat slug.

FIG. 9 illustrates a schematic top view of a package that includes multiple integrated devices and at least one heat slug.

FIGS. 10A, 10B, and 10C, together, illustrate aspects of an exemplary sequence for fabricating a package.

FIGS. 11A, 11B, and 11C, together, illustrate aspects of another exemplary sequence for fabricating a package.

FIG. 12 illustrates an exemplary flow chart of a method for fabricating a package.

FIG. 13 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, well-known circuits, structures, techniques, etc. may not be shown in detail in order not to obscure the aspects of the disclosure. As another example, various devices and structures disclosed herein are illustrated schematically. Such schematic representations are not to scale and are generally intentionally simplified. To illustrate, integrated devices can have many tens or hundreds of contacts and corresponding interconnections; however, a very small number of such contacts and interconnects are illustrated herein to highlight important features of the disclosure without unduly complicating the drawings.

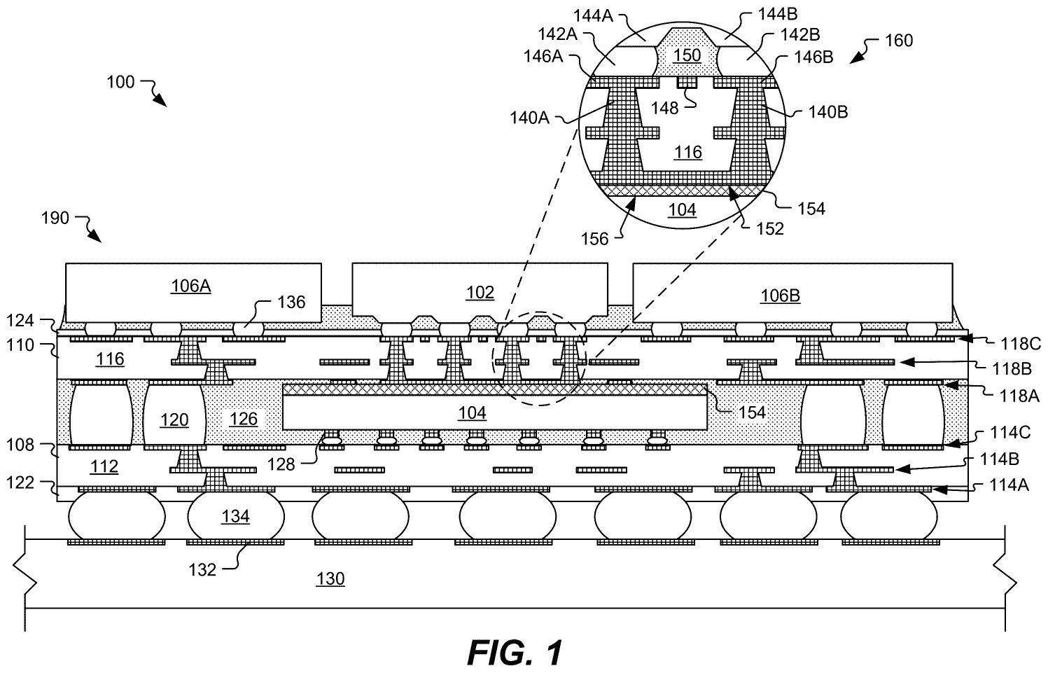

Particular aspects of the present disclosure are described below with reference to the drawings. In the description, common features are designated by common reference numbers. In some drawings, multiple instances of a particular type of feature are used. Although these features are physically and/or logically distinct, the same reference number is used for each, and the different instances are distinguished by addition of a letter to the reference number. When the features as a group or a type are referred to herein, e.g., when no particular one of the features is being referenced, the reference number is used without a distinguishing letter. However, when one particular feature of multiple features of the same type is referred to herein, the reference number is used with the distinguishing letter. For example, referring to FIG. 1, multiple integrated devices are illustrated and associated with reference numbers 106A and 106B. When referring to a particular one of these integrated devices, such as an integrated device 106A, the distinguishing letter “A” is used. However, when referring to any arbitrary one of these integrated devices or to these integrated devices as a group, the reference number 106 is used without a distinguishing letter.

As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and may subsequently be referred to in the singular or optional plural (as indicated by “(s)”) unless aspects related to multiple of the features are being described.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

Improvements in manufacturing technology and demand for lower cost and more capable electronic devices has led to increasing complexity of integrated circuits (ICs). Often, more complex ICs have more complex interconnection schemes to enable interaction between ICs of a device. The number of interconnect levels for circuitry has substantially increased due to the large number of devices that are now interconnected in a state-of-the-art mobile application device.

These interconnections include back-end-of-line (BEOL) interconnect layers, which may refer to the conductive interconnect layers for electrically coupling to front-end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle-of-line (MOL) interconnect layers, which interconnect to the FEOL active devices of an IC. As used herein, the term “layer” includes a film, and is not construed as indicating a vertical or horizontal thickness unless otherwise stated.

State-of-the-art IC designs often demand a small form factor, low cost, a tight power budget, high electrical performance, and substantial heat management. IC package technologies strives to meet these divergent goals. However, in many cases, these goals are in conflict. For example, smaller form factors can make it challenging to manage heat. Various aspects of the present disclosure address the problem of providing adequate heat management in a small form factor package.

### Exemplary Packages Including Substrates, Integrated Devices and a Heat Slug

FIG. 1 illustrates a schematic cross sectional profile view of a system 100 including a package 190 that includes multiple integrated devices and at least one heat slug 102. In FIG. 1, the integrated devices include an integrated device 104, an integrated device 106A, and an integrated device 106B.

Each of the integrated devices 104, 106 includes integrated circuitry, such as a plurality of transistors and/or other circuit elements arranged and interconnected to form logic cells, memory cells, etc. Components of the integrated circuitry can be formed in and/or over a semiconductor substrate. Different implementations can use different types of transistors, such as a field effect transistor (FET), planar FET, finFET, a gate all around FET, or mixtures of transistor types. In some implementations, an FEOL process may be used to fabricate the integrated circuitry in and/or over the semiconductor substrate.

In some embodiments, one or more of the integrated devices 104, 106 includes or corresponds to a microcontroller, an application specific integrated circuit (ASIC), a field programmable gate array (FPGA), a central processing unit (CPU) having one or more processing cores, an application processor, a processing system, or a system on chip (SoC). In the same or different embodiments, one or more of the integrated devices 104, 106 includes or corresponds to a memory device, such as a static random-access memory (SRAM), a dynamic random-access memory (DRAM), flash memory, read-only memory (ROM), programmable read-only memory (PROM), erasable programmable read-only memory (EPROM), electrically erasable programmable read-only memory (EEPROM), a solid-state storage device (SSD), or a combination thereof. In the same or different embodiments, one or more of the integrated devices 104, 106 includes or corresponds to another type of device, such as a power management integrated circuit (PMIC), a modem, a radio frequency (RF) device (e.g., one or more amplifiers), a light emitting diode (LED) integrated device, and/or a microelectromechanical (MEM) device (e.g., a surface acoustic wave (SAW) filter, a bulk acoustic wave (BAW) filter). Further, one or more of the integrated devices 104, 106 can include any combination of the components listed above, and optionally various passive components (e.g., capacitors, inductors, resistors, or conductors) arranged and interconnected to form other circuit elements.

The integrated devices 104, 106 include or correspond to semiconductor dies. For example, in some embodiments, each of the integrated devices 104, 106 corresponds to a single semiconductor die. In other examples, one or more of the integrated devices 104, 106 includes two or more semiconductor dies arranged in a stacked configuration. In such examples, the two or more semiconductor dies can include chiplets, where the term “chiplet” refers to an integrated circuit block, a functional circuit block, or other like circuit block specifically designed to work with one or more other chiplets to form a larger, more complex chiplet architecture. To illustrate, one or more of the integrated devices 104, 106 can include two or more chiplets arranged and interconnected as a three-dimensional (3D) IC device. In the same or different example, one or more of the integrated devices 104, 106 includes one or more semiconductor dies and one or more additional components, such as an interposer device, one or more passive components, etc.

In some implementations, one or more of the integrated devices 104, 106 can include or correspond to a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one or more of the integrated devices 104, 106). Using several chiplets that perform several functions may reduce the overall cost of a package relative to using a single chip to perform all of the functions.

In some implementations, one or more of the chiplets and/or one or more of the integrated devices 104, 106 described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

An advantage of splitting a set of functions among several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or differently configured first integrated device. This saves cost by avoiding redesign the first chiplet, when packages with improved integrated devices are fabricated.

The integrated devices 104, 106 are coupled to one or more substrates, including a substrate 108 and a substrate 110. For example, one or more of the integrated devices 104, 106 can be electrically connected to, or integrated with, a respective substrate via one or more contacts or interconnects, such as for example, microbumps, conductive pillars, conductive pads (e.g., for pad to pad bonding), or other similar electrical interconnects. In the example illustrated in FIG. 1, the integrated devices 104 and 106 are arranged in a package-on-package configuration. For example, the integrated devices 106 are coupled to the substrate 110, and the substrate 110 is disposed between the integrated devices 106 and the integrated device 104. In this arrangement, the substrate 108 is a package substrate of the package 190 and includes off-package contacts 134 to enable the package 190 to be coupled to contacts 132 of a circuit board 130 or another device.

Each substrate 108, 110 includes multiple metal layers separated by one or more dielectric layers. For example, the substrate 108 is illustrated as including three metal layers 114, including a metal layer 114A, a metal layer 114B, and a metal layer 114C separated from one another by a dielectric 112. As another example, the substrate 110 is illustrated as including three metal layers 118, including a metal layer 118A, a metal layer 118B, and a metal layer 118C separated from one another by a dielectric 116. The metal layers 114, 118 are patterned to define contacts, conductive traces and optionally other features, such as coils of an inductor. The metal layers 114, 118 of each substrate 108, 110 are interconnected with one another at various locations by vias to provide conductive pathways through the thickness of each substrate 108, 110.

In FIG. 1, the substrate 108 also includes a solder resist layer 122 that includes openings exposing contacts of the metal layer 114A to which the off-package contacts 134 are electrically connected. The substrate 108 also includes contacts 128 electrically connected to the integrated device 104. The metal layers 114 of the substrate 108 define conductive paths between the contacts 128 and the off-package contacts 134, between the contacts 128 and conductive interconnects 120, or both.

The conductive interconnects 120 electrically connect the substrate 108 and the substrate 110. The conductive interconnects 120 can include copper clad balls, pillars, or other conductive features that extend between the substrates 108, 110 to enable communication between the integrated device 104 and one or more of the integrated devices 106, to enable communication between one or more of the integrated devices 106 and one or more off-package devices coupled to the circuit board 130, to enable provision of power from the circuit board 130 to the integrated devices 106, or a combination thereof.

In the example illustrated in FIG. 1, a mold compound 126 is disposed within a region between the substrates 108, 110. For example, the mold compound 126 at least partially encapsulates the integrated device 104, the conductive interconnects 120, or both. The mold compound 126 is optional and is omitted in some embodiments.

In FIG. 1, the substrate 110 also includes a solder resist layer 124 that includes openings exposing contacts of the metal layer 118C. The integrated devices 106 are electrically connected by electrical interconnects 136 to respective contacts of the metal layer 118C through the openings in the solder resist layer 124. The metal layers 118 of the substrate 110 define conductive paths between the integrated devices 106 and the conductive interconnects 120.

The substrate 110 also includes a plurality of through substrate vias 140 (most clearly seen in inset diagram 160) thermally coupled to the heat slug 102 and to the integrated device 104. For example, in FIG. 1, the through substrate vias 140 are illustrated as stacked vias that extend between contacts 146 on a first side of the substrate 110 and one or more contacts 152 on a second side of the substrate 110.

In the example illustrated in FIG. 1, a layer 154 is disposed between an upper surface 156 of the integrated device 104 and the one or more contacts 152. The layer 154 can include a thin layer of the mold compound 126, a thermal interface material, or an adhesive. In some embodiments, characteristics of the layer 154 (such as material properties of the layer 154, a thickness of the layer 154, etc.) are selected to improve heat conduction from the integrated device 104 to the heat slug 102. In other embodiments, the characteristics of the layer 154 are selected to not significantly limit heat conduction from the integrated device 104 to the heat slug 102. In still other embodiments, the layer 154 is omitted. In such embodiments, the contact(s) 152 are disposed in direct and intimate contact (i.e., with no intervening layers) with the upper surface 156 of the integrated device 104.

In a particular aspect, the heat slug 102 defines multiple protrusions 144, and the contacts 146 of the vias 140 are coupled to the protrusions 144 of the heat slug 102. For example, in FIG. 1, each protrusion 144 of the heat slug 102 is coupled to a respective contact 146 using solder 142. To illustrate, in the inset diagram 160, protrusion 144A of the heat slug 102 is coupled to contact 146A by solder 142A, and protrusion 144B of the heat slug 102 is coupled to contact 146B by solder 142B.

A technical advantage of configuring the heat slug 102 with the protrusions 144 is that the protrusions 144 facilitate use of conventional surface mount techniques to couple the heat slug 102 to other components of the package 190. For example, during reflow of the solder 142, the protrusions 144 act like pins or posts of a flip chip device. Thus, the same factors that contribute to reliable attachment of the integrated device(s) 106 to the substrate 110 contribute to reliable attachment of the heat slug 102 to the substrate 110. Such surface mount techniques are widely used, relatively inexpensive, and readily controlled leading to inexpensive, reliable fabrication of the package 190 including the heat slug 102.

An additional technical advantage of configuring the heat slug 102 with the protrusions 144 is that the protrusions 144 allow the heat slug 102 to stand off from the substrate 110 similar to a conventional flip chip or surface mount component which can improve warpage characteristics of the package 190 as compared to, for example, use of a heat slug that includes a flat bottom surface rather than the protrusion 144. For example, a flat-bottomed heat slug could be coupled to the substrate 110 using a thermal interface material. In this arrangement, stresses on the substrate 110 due to interaction with the flat-bottomed heat slug can be very different from stresses on the substrate 110 due to interaction with the integrated device(s) 106. This uneven distribution of stresses can increase the risk of warpage. In contrast, by configuring the heat slug 102 with the protrusions 144, the stresses on the substrate 110 due to interaction with the heat slug 102 are more similar to the stresses on the substrate 110 due to interaction with the integrated device(s) 106; thereby reducing the risk of warpage.

An additional technical advantage of configuring the heat slug 102 with the protrusions 144 is that using the protrusions 144 allows for space between the contacts 146 to route other conductive traces. For example, in FIG. 1, one or more routing traces 148 are disposed in the metal layer 118C between a pair of adjacent contacts 146A, 146B. Providing room in the metal layer 118C for the routing traces 148 means that the routing traces 148 do not need to be routed in lower metal layers (e.g., the metal layer 118B or 118C), which can enable use of shorter conductive paths between devices (which improves performance), can enable reduction of the number of metal layers 118 of the substrate 110, can reduce the cost and complexity of fabrication of the substrate 110 (e.g., by reducing the number of vias needed to interconnect the metal layers 118 of the substrate), or a combination thereof.

A further technical advantage of configuring the heat slug 102 with the protrusions 144 is that one or more of the protrusions 144 can be electrically connected, via solder 142, to a contact 146 that is coupled to a ground of the substrate 110. In this arrangement, the heat slug 102 can also provide electromagnetic shielding for components of the package 190. For example, in FIG. 1, the heat slug 102 is disposed between the integrated device 106A and the integrated device 106B. In this arrangement, the heat slug 102 shields the integrated device 106A from electromagnetic interference due to the integrated device 106B, and vice versa. Likewise, the heat slug 102 can also provide electromagnetic shielding between the integrated device 104 and one or more other components disposed over the heat slug 102 (e.g., other components of a device in which the package 190 is integrated).

The protrusions 144 are spaced apart from one another at a distance selected to (e.g. configured to) facilitate even distribution of an underfill material 150. For example, the underfill material 150 can be disposed between the heat slug 102 and the substrate 110 in a region between two or more of the protrusions 144. As explained further below, the underfill material 150 can be applied using conventional underfill techniques at the same time that underfill material associated with the integrated device(s) 106 is applied.

In a particular aspect, the heat slug 102 is a unitary (e.g., monolithic) mass of metal (e.g., copper, aluminum, or another metal or alloy). For example, the heat slug 102 can be machined from a solid block of metal to define the protrusions 144 (e.g., using a milling technique, selective etching, or another subtractive process). Alternatively, the heat slug 102 with the protrusions 144 can be formed using an additive process, such as casting, laser sintering, selective melting, etc.

In the example illustrated in FIG. 1, at least part of the heat slug 102 vertically overlaps with at least part of the integrated device 104 and the through substrate vias 140 are stacked vias arranged one over the other. In other embodiments, the heat slug 102 is vertically offset from the integrated device 104, in which case the through substrate vias 140 are also offset from one another to provide a continuous thermal path between the contact(s) 152 and the contacts 146.

The heat slug 102 is configured to facilitate removal of heat from the integrated device 104. For example, integrated circuit components of the integrated device 104 can generate heat as a result of normal operation. To illustrate, if the integrated device 104 includes one or more processing cores, heat generated during processing operations can increase the temperature in some local regions of the integrated device 104 above a threshold temperature at which operation of the integrated device 104 is throttled to avoid damaging the integrated device 104 (e.g., due to thermal stresses, electromigration, etc.). The heat slug 102 is thermally coupled to the integrated device 104 by the through substrate vias 140 to provide a relatively large thermal mass to extract heat from the integrated device 104. In some embodiments, an upper surface of the heat slug 102 can be thermally coupled to one or more additional heat mitigation devices (e.g., a heat exchanger of a device in which the package 190 is integrated) to remove heat from the heat slug 102. Additionally, or alternatively, the heat slug 102 can include features to facilitate removal of the heat, such as fins, pins, or other features that improve heat removal from the heat slug 102 at or near an upper surface of the heat slug 102. In such arrangements, the heat slug 102 may also, or alternatively, be referred to as a heat sink.

The specific number and arrangement of layers of the substrate 108 and the substrate 110 in FIG. 1 is merely illustrative and should not be considered limiting. For example, the substrate 108 can include more than three metal layers 114 or fewer than three metal layers 114. Likewise, the substrate 110 can include more than three metal layers 118 or fewer than three metal layers 118. Additionally, the number and arrangement of the contacts 128, the conductive interconnects 120, the interconnects 136, the through substrate vias 140, the contacts 146, the protrusions 144, and the off-package contacts 134 is merely illustrative and should not be considered limiting. In other examples, the package 190 includes different numbers and/or arrangements of any of these.

Further, while the package 190 of FIG. 1 is illustrated as including three integrated devices 104, 106 in a package-on-package arrangement, in other examples, the package 190 can include more than three or fewer than three integrated devices 104, 106 in a package-on-package arrangement or in a different arrangement. Additionally, the heat slug 102 need not be disposed between two integrated devices 106 as illustrated in FIG. 1. For example, the integrated devices 106A and 106B can be positioned adjacent to one another with the heat slug 102 to one side or the other in the perspective illustrated in FIG. 1.

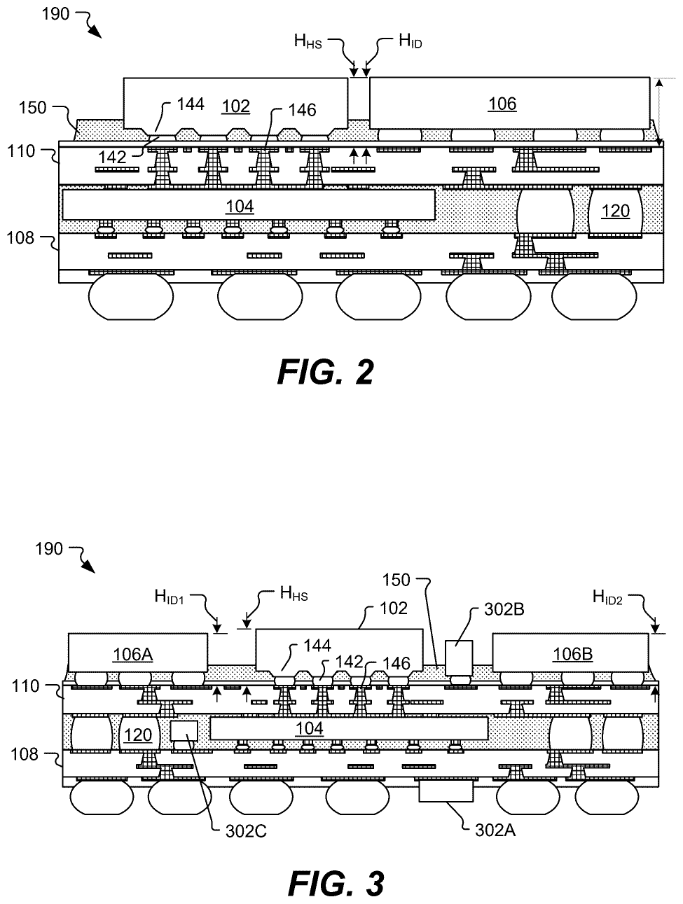

FIGS. 2-4 illustrate schematic cross sectional profile views of various optional configurations of the package 190 of FIG. 1. In each of FIGS. 2-4, the package 190 includes multiple integrated devices and at least one heat slug 102. For example, each of the packages 190 of FIGS. 2-4 includes at least one integrated device 104 coupled to the substrate 108 and at least one integrated device 106 and at least one heat slug 102 coupled to the substrate 110. Further, in each of FIGS. 2-4, the substrate 110 is disposed between the integrated device(s) 106 and the integrated device(s) 104.

As described with reference to FIG. 1, each of the integrated devices 104, 106 includes or corresponds to at least one semiconductor die and possibly one or more additional components, such as an interposer device, one or more passive components, etc. Additionally, each of the substrates 108, 110 includes any combination of the features and configurations described with reference to FIG. 1. For example, the substrate 110 also includes the through substrate vias 140 of FIG. 1 thermally coupled to the heat slug 102 and to the integrated device 104.

The heat slug 102 of each of FIGS. 2-4 defines the protrusions 144, and the contacts 146 of the vias 140 are coupled to the protrusions 144 of the heat slug 102 using solder 142. Additionally, in FIGS. 2-4, the underfill material 150 is disposed on an upper surface of the substrate 110, including between the heat slug 102 and the substrate 110 in a region between two or more of the protrusions 144. In the examples illustrated in each of FIGS. 2-4, the layer 154 is omitted; however, as explained above, the layer 154 is optional, and may be present in any of FIGS. 2-4. Thus, in each of FIGS. 2-4, the package 190 provides some or all of the technical benefits described with reference to FIG. 1.

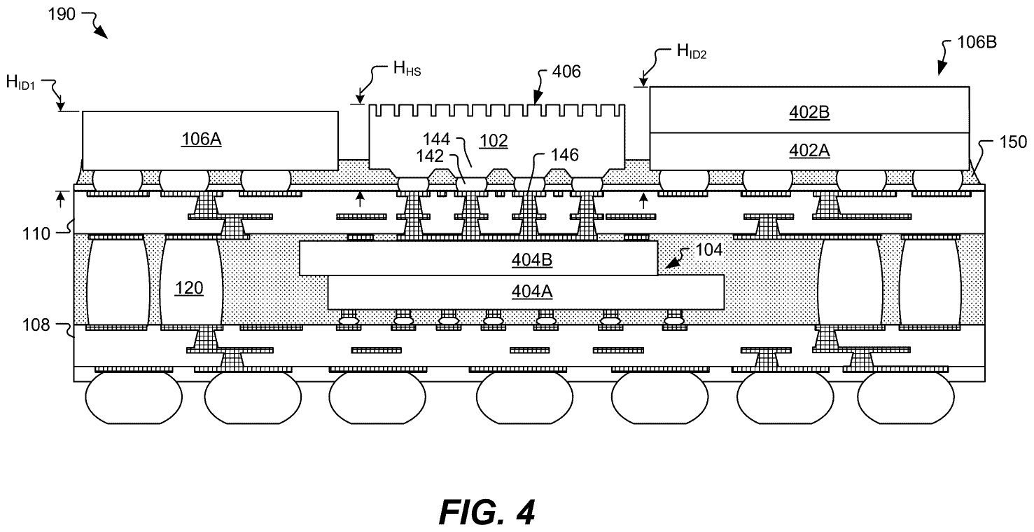

FIGS. 2-4 also illustrate various vertical positions and/or dimensional differences among portions of the package 190 in different embodiments. For example, in the example illustrated in FIGS. 2-4, a height (H_{ID}) of the integrated device 106 indicates a distance between an upper surface of the integrated device 106 and an upper surface of the substrate 110, and a height (H_{HS}) of the heat slug 102 indicates a distance between an upper surface of the heat slug 102 and an upper surface of the substrate 110. Where more than one integrated device 106 is shown (e.g., in FIG. 3) heights of the integrated device include a numeral to distinguish them from one another. To illustrate, in FIG. 3, the integrated device 106A has a first height (H_{ID1}) and the integrated device 106B has a first height (H_{ID2}).

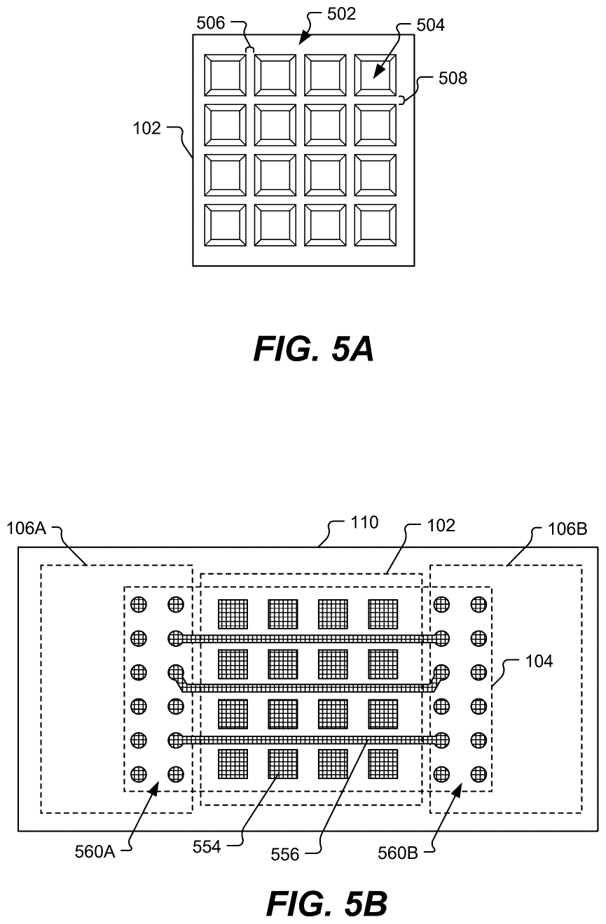

In the example illustrated in FIG. 2, the height (H_{ID}) of the integrated device 106 is approximately equal to the height (H_{HS}) of the heat slug 102. In the example illustrated in FIG. 3, the height (H_{ID1}) of the integrated device 106A is less than the height (H_{HS}) of the heat slug 102. Further, in FIG. 3, the height (H_{ID1}) of the integrated device 106A is approximately equal to the height (H_{ID2}) of the integrated device 106B. In the example illustrated in FIG. 4, the height (H_{ID1}) of the integrated device 106A is less than the height (H_{HS}) of the heat slug 102, and the height (H_{ID2}) of the integrated device 106B is greater than the height (H_{HS}) of the heat slug 102.

Differences in the heights of the integrated device(s) 106 and the heat slug(s) 102 can be due to differences in how the integrated device(s) 106 and the heat slug(s) 102 are connected to the substrate 110, differences in thicknesses of the integrated device(s) 106 and the heat slug(s) 102, other factors, or a combination thereof. Further, although several examples are illustrated in FIGS. 2-4, other differences in the heights of the various devices coupled to the substrate 110 can be used in other embodiments. To illustrate, when two or more heat slugs 102 are coupled to the substrate 110, the heat slugs can have the same heights or different heights.

FIG. 2 illustrates a schematic cross sectional profile view of a configuration of the package 190 in which the heat slug 102 is shifted to one side of the package 190. In the view illustrated in FIG. 2, only one integrated device 106 electrically connected to a top substrate (e.g., the substrate 110) is visible; however, in some embodiments, the package 190 of FIG. 2 can optionally include one or more additional integrated devices electrically connected to the top substrate (e.g., the substrate 110) in a location that is obscured (e.g., by the heat slug 102, the integrated device 106, or both) in the view shown in FIG. 2.

In some examples, the heat slug 102 is shifted to one side of the package 190 to better align the heat slug 102 with regions of the integrated device 104 that are associated with greater heat removal demand. In such examples, disposing the heat slug 102 closer to such regions may enable more efficient or effective heat removal.

In some examples, the heat slug 102 is additionally, or alternatively, shifted to one side of the package 190 to improve electromagnetic shielding effects of the heat slug 102. For example, during use, the package 190 can be disposed within a larger device that includes components that generate significant electromagnetic radiation. In this example, the heat slug 102 and/or the integrated device 104 can be positioned in the package 190 such that the heat slug 102 is well positioned to shield the integrated device 104 from the electromagnetic radiation generated by these components.

In the same or different examples, the heat slug 102 can be shifted to one side to facilitate better positioning of the integrated device(s) 106. For example, the integrated device(s) 106 may be associated with a large number of conductive interconnects 120 to facilitate communication. In this example, the heat slug 102 can be positioned to one side to enable more efficient positioning of the conductive interconnects 120.

FIG. 3 illustrates a schematic cross sectional profile view of a configuration of the package 190 in which the package 190 includes one or more additional components, such as one or more passive devices 302. FIG. 3 illustrates three passive devices 302, including a passive device 302A, a passive device 302B, and a passive device 302C. The passive devices 302 can include, for example and without limitation, capacitive devices, inductive devices, or resistive devices. To illustrate, a passive device 302 that includes one or more capacitors can be electrically connected to a power distribution network (PDN) of one of the integrated devices 104, 106 to improve performance of the PDN. As another illustrative example, a passive device 302 that includes one or more capacitors, one or more inductors, one or more resistors, or a combination thereof, can be electrically connected to a radiofrequency component to adjust impedance of one or more circuits.

The passive devices 302 of FIG. 3 are illustrated at various representative, non-limiting, locations within the package 190. For example, the passive device 302A is illustrated as a landside device (e.g., a device coupled to the substrate 108 in a die shadow of the integrated device 104). As another example, the passive device 302B is illustrated as a surface mounted device electrically connected to the substrate 110, and the passive device 302C is illustrated as a surface mounted device electrically connected to the substrate 108. Three passive devices 302 are illustrated merely to highlight specific possible placements of the passive devices 302. In other embodiments, the package 190 can include more than three or fewer than three passive devices 302. Further, in other embodiments, the package 190 can include one or more passive devices disposed in a different location, such as embedded within one or both of the substrates 108, 110.

FIG. 4 illustrates a schematic cross sectional profile view of a configuration of the package 190 in which one or more of the integrated devices 104, 106 includes stacked dies. For example, in FIG. 4, the integrated device 104 includes a die 404A and a die 404B arranged in a die stack. Further, in FIG. 4, the integrated device 106B includes a die 402A and a die 402B arranged in a die stack. The integrated device 106A of FIG. 4 is illustrated as a single die; however, in other examples, the integrated device 106A can include two or more dies arranged in a die stack. The specific integrated devices 104, 106 including two or more dies arranged in a die stack illustrated in FIG. 4 is illustrative. In other examples, the package 190 can include a different combination of individual dies and dies stacks.

The example illustrated in FIG. 4 also shows an upper surface 406 of the heat slug 102 including features to facilitate heat removal. In particular, in FIG. 4, the upper surface 406 of the heat slug 102 includes fins, pins, or other features configured to increase a surface area available for heat exchange.

The package 190 can include a heat slug 102 with the features to facilitate heat removal illustrated in FIG. 4 irrespective of whether the package also includes one or more die stacks. Likewise, the package 190 can include one or more die stacks irrespective of whether the package 190 includes a heat slug 102 that includes the features to facilitate heat removal illustrated in FIG. 4. Further, the package 190 can include combinations of the features illustrated in FIGS. 1-4. For example, a package 190 that includes the heat slug 102 offset to one side can include one or more passive devices (as in FIG. 3), one or more die stacks (as in FIG. 4), features to facilitate heat removal on an upper surface 406 of the heat slug 102, or any combination thereof. As another example, a package 190 that includes one or more passive devices (as in FIG. 3) can also include one or more die stacks (as in FIG. 4), features to facilitate heat removal on an upper surface 406 of the heat slug 102, or any combination thereof. Other combinations of the above features are also envisioned.

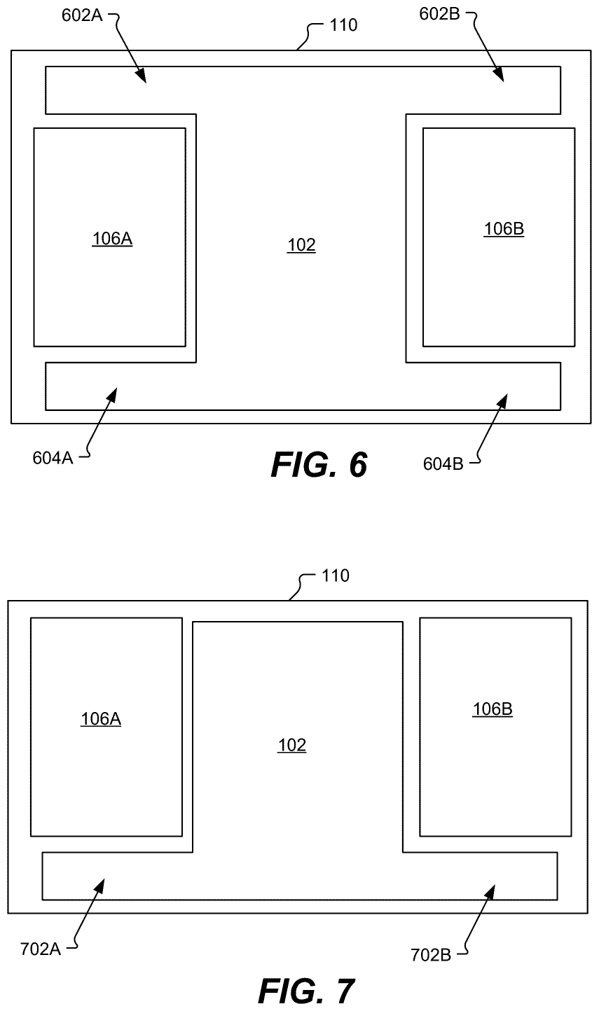

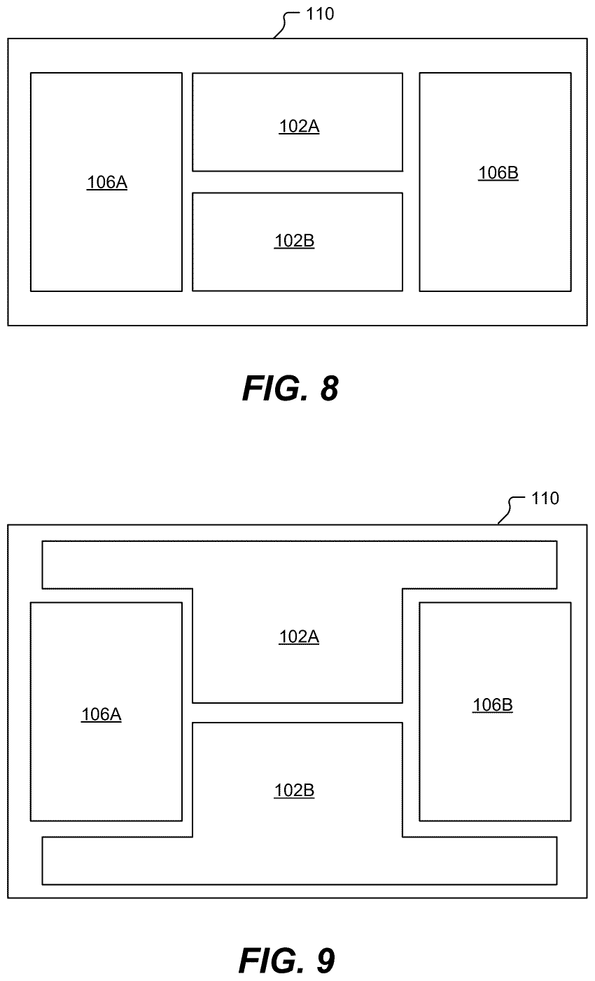

FIG. 5A illustrates a schematic bottom view of an example of the heat slug 102 of the package of FIG. 1. FIG. 5B illustrates a top view of an example of the substrate 110 with other features of the package outlined in dotted lines to indicate relative positions of such features. For example, FIG. 5B shows an output of the heat slug 102, the integrated device 104, and the integrated devices 106 arranged in the manner described with reference to FIG. 1.

In the example illustrated in FIG. 5A, a plurality of protrusions 504, which correspond to specific examples of the protrusions 144 of any of FIGS. 1-4, are defined on a bottom surface 502 of the heat slug 102. The protrusions 504 are arranged in a plurality of rows and a plurality of columns. The rows are spaced apart by a distance 508, and the columns are spaced apart by a distance 506. In the example illustrated, the distance 506 is approximately equal to the distance 508; however, in other examples, the distances 506, 508 can differ from one another. Further, in some examples, the distance 508 varies between two or more pairs of adjacent rows, the distance 506 varies between two or more pairs of adjacent columns, or both. To illustrate, while FIG. 5A shows the protrusions 504 arranged in a grid, in other examples, the protrusions 504 can be arranged in another pattern. As an example, the arrangement of the protrusions 504 can be selected based on where contacts (e.g., contacts 554 FIG. 5B) of the substrate 110 to which the heat slug 102 will be attached can be conveniently positioned. The distances 506, 508 can additionally be selected to facilitate even distribution of an underfill material beneath the heat slug 102. For example, one or both of the distances 506, 508 can be selected based on viscosity or other flow characteristics of the underfill material.

In FIG. 5B, an upper metal layer of the substrate 110 is patterned to define the contacts 554 and contacts 560 associated with the integrated devices 106. The contacts 554 are arranged in a grid corresponding to the pattern and placement of the protrusions 504 of the heat slug 102 of FIG. 5A. The contacts 560 include contacts 560A electrically connected to the integrated device 106A and contacts 560B electrically connected to the integrated device 106B.

Optionally, the upper metal layer of the substrate 110 is also patterned to define one or more routing traces 556. For example, in FIG. 5B, the routing traces 556 extend between adjacent rows of the contacts 554. In FIG. 5B, the routing traces 556 are arranged to electrically connect the integrated device 106A and the integrated device 106B; however, in other examples, one or more of the routing traces 556 can be configured to provide a conductive path between two or more different devices or between one of the integrated devices 106 and another device.

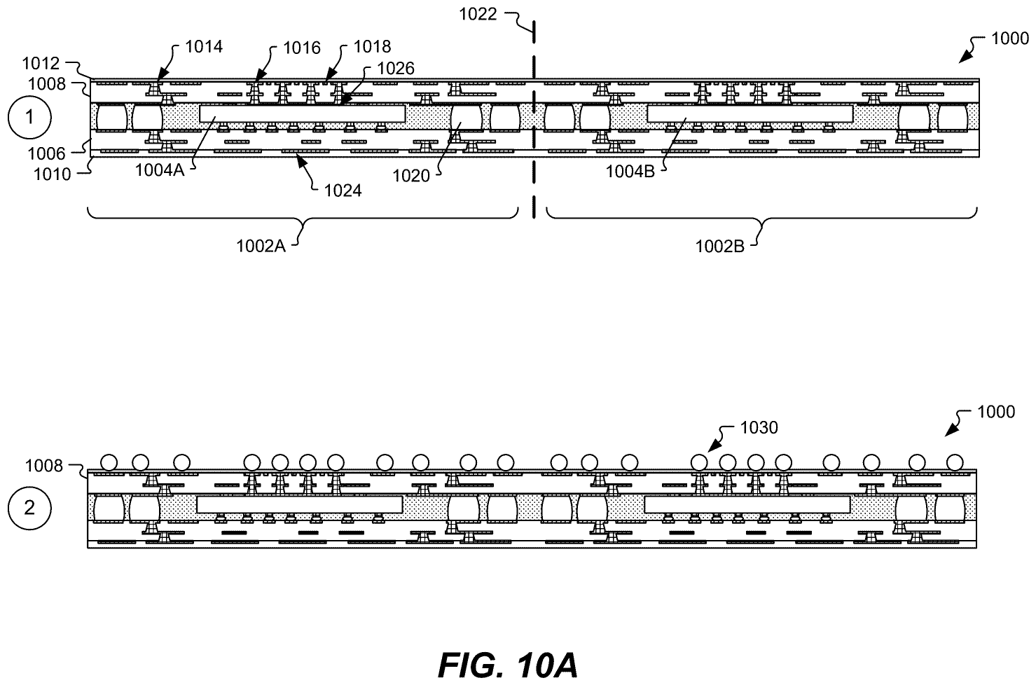

FIGS. 6-9 illustrate schematic top views of various optional configurations of the package 190 of FIG. 1. In each of FIGS. 6-9, the package 190 can include any of the features, configuration, or aspects described with reference to FIGS. 1-5B. For example, although only a subset of features are visible, each of the packages 190 of FIGS. 6-9 can include at least one integrated device 104 coupled to a substrate 108 and include at least one integrated device 106 and at least one heat slug 102 coupled to the substrate 110, where the substrate 110 is disposed between the integrated device(s) 106 and the integrated device(s) 104. Further, the various optional configurations of FIGS. 6-9 are merely illustrative of particular aspects and are not limiting.

In FIG. 6, the heat slug 102 has a shape selected to cover portions of the substrate 110 that are not covered by the integrated devices 106. In the particular example illustrated, the heat slug 102 has an “I” shape, with portions 602A and 604A of the heat slug 102 extending between the integrated device 106A and opposite edges of the substrate 110, and portions 602B and 604B of the heat slug 102 extending between the integrated device 106B and the opposite edges of the substrate 110.

Configuring the heat slug 102 in the manner illustrated in FIG. 6 can give the heat slug 102 a greater surface area, a greater volume, or both, relative to the example illustrated in FIGS. 5A and 5B. A greater volume of the heat slug 102 is associated with a corresponding larger thermal mass, which enables the heat slug 102 to remove more heat from the integrated device 104. A greater surface area of the heat slug 102 improves the efficiency of heat removal from the heat slug 102.

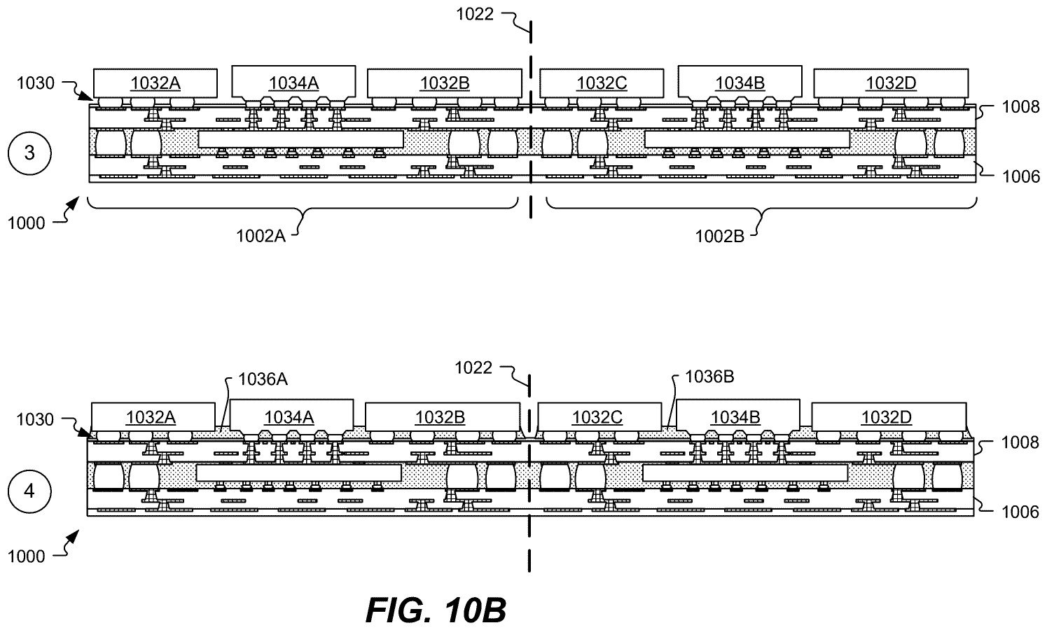

FIG. 7 illustrates another example in which the heat slug 102 has a shape selected to cover portions of the substrate 110 that are not covered by the integrated devices 106. In the particular example illustrated in FIG. 7, the heat slug 102 has a “T” shape, with a portion 702A of the heat slug 102 extending between the integrated device 106A and an edge of the substrate 110, and a portion 702B of the heat slug 102 extending between the integrated device 106B and the edge of the substrate 110. The configuration illustrated in FIG. 7 has similar benefits as the configuration illustrated in FIG. 6 but may be better suited for use in situations in which the integrated devices 106 are shifted toward one edge of the substrate 110 rather than substantially centered as in FIG. 6.

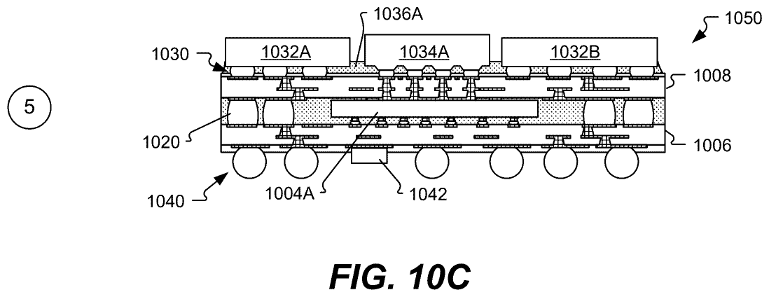

FIG. 8 illustrates another example that includes two or more heat slugs 102, such as a heat slug 102A and a heat slug 102B. The heat slugs 102 of FIG. 8 can be identical or can differ from one another. For example, protrusions of the heat slug 102A can have a different spacing or arrangement than the protrusions of the heat slug 102B. Using identical heat slugs 102 may reduce manufacturing costs while also enabling positioning of each of the heat slugs 102 at specific locations, such as over hot spots of an integrated device from which heat is to be removed. Using heat slugs 102 with different configurations can enable customization of heat slugs 102 for different characteristics, such as to provide better heat removal or electromagnetic shielding in some areas. Using two or more heat slugs 102 can also improve flexibility for routing of traces on a top metal layer of the substrate 110 or for positioning of other components (e.g., one or more of the passive device(s) 302 of FIG. 3).

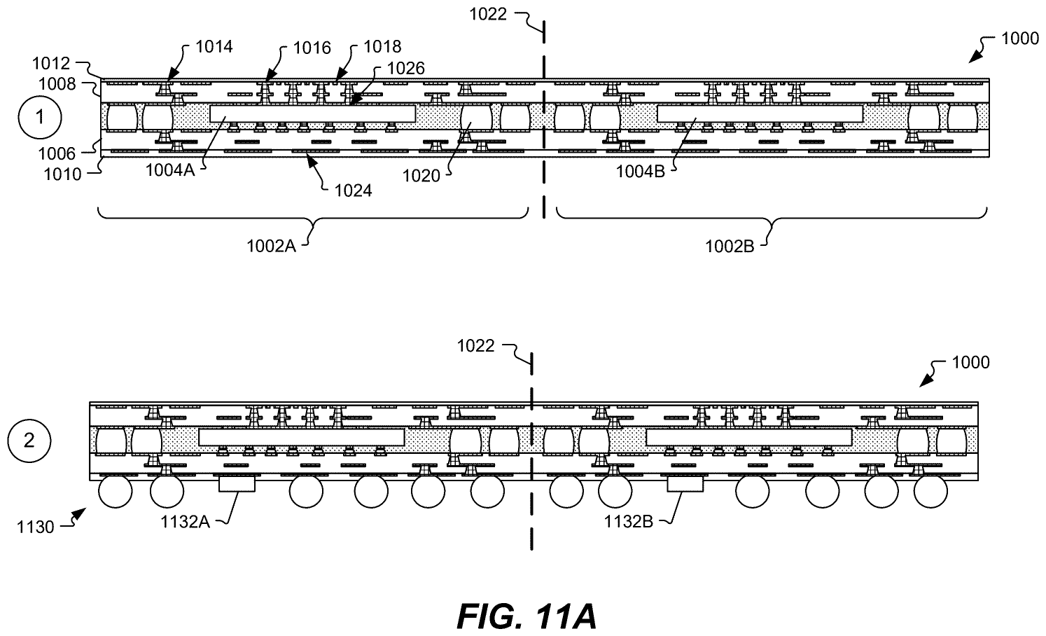

FIG. 9 illustrates another example that includes two or more heat slugs 102, such as a heat slug 102A and a heat slug 102B. In FIG. 9, each of the heat slugs 102 has a “T” shape, as described with reference to FIG. 7, and together, the heat slugs 102 form an “I” shape. In some embodiments, using two “T” shaped heat slugs 102 may reduce manufacturing complexity as compared to using a single “I” shaped heat slug 102. Additionally, as described with reference to FIG. 8, the heat slugs 102 of FIG. 9 can be identical or can differ from one another.

### Exemplary Sequence for Fabricating a Package Including Substrates, Integrated Devices and a Heat Slug

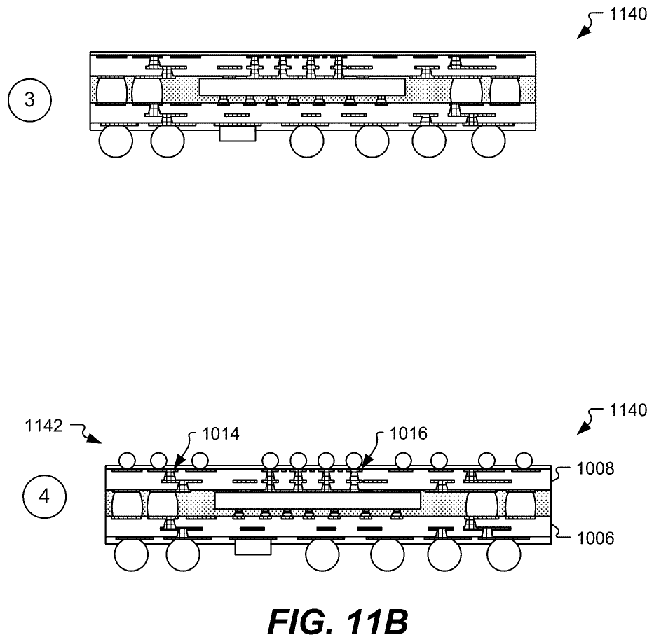

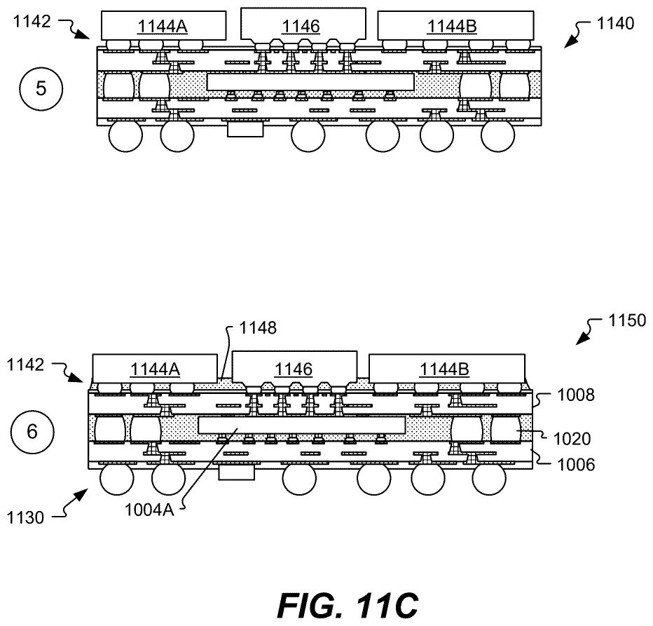

In some implementations, fabricating a package includes several processes. FIGS. 10A-10C illustrate a first exemplary sequence for providing or fabricating a package, and FIGS. 11A-11C illustrate a second exemplary sequence for providing or fabricating a package. In some implementations, the sequence of FIGS. 10A-10C or the sequence of FIGS. 11A-11C may be used to provide or fabricate the package 190 of any of FIGS. 1-4, which can include any of the configurations described with reference to FIGS. 5-9.

It should be noted that the sequences of FIGS. 10A-10C and FIGS. 11A-11C may combine one or more stages in order to simplify and/or clarify the sequence for providing or fabricating the package. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIGS. 10A-10C and FIGS. 11A-11C.

FIGS. 10A and 10B illustrate stages associated with operations performed at a strip level or a panel level. Thus, each Stage illustrated in FIGS. 10A and 10B includes features of multiple packages. Specifically, in FIGS. 10A and 10B, an assembly 1000 includes features of two packages before individuation; and FIG. 10C illustrates a Stage after individuation of a single package from the assembly 1000. The assembly 1000 of FIGS. 10A and 10B includes features of two packages merely as one example. In other examples, the assembly 1000 can include features of more than two packages. In still other examples, a package can be assembled individually, in which case the assembly 1000 would include features of a single package.

Stage 1 of FIG. 10A illustrates a state after formation of the assembly 1000. The assembly 1000 includes one or more integrated devices 1004 (e.g., an integrated device 1004A and an integrated device 1004B) disposed between two substrates, including a substrate 1006 and a substrate 1008. Each of the integrated device(s) 1004 corresponds to an example or instance of the integrated device 104 of FIG. 1.

The substrate 1006 in FIG. 10A includes the features of the substrate 108 of FIG. 1, repeated multiple times side-by side and separated from one another by a singulation line 1022. For example, features 1002A on a first side of the singulation line 1022 correspond to or will be included within a first package and features 1002B on a second side of the singulation line 1022 correspond to or will be included within a second package. The substrate 1006 includes multiple metal layers separated from one another by one or more dielectric layers and patterned to form contacts, traces, pads, etc. and interconnected by vias. The substrate 1006 can also include a solder resist layer 1010 or another protective layer or passivation layer through which various pads and/or contacts (e.g., off-package contacts 1024) can be accessed.

Likewise, the substrate 1008 includes multiple metal layers separated from one another by one or more dielectric layers and patterned to form contacts, traces, pads, etc. and interconnected by vias. In particular, the substrate 1008 includes contacts 1014 for one or more integrated devices 1032 (shown at Stage 3 of FIG. 10B) and one or more contacts 1016 for one or more heat slugs 1034 (shown at Stage 3 of FIG. 10B). The contacts 1016 correspond to examples of the contacts 146 of FIG. 1. For example, each of the contacts 1016 is thermally coupled (through one or more vias in the substrate 1008) to one or more contact 1026 on a side of the substrate 1008 adjacent to a respective one of the integrated devices 1004. Each of the contact(s) 1026 is thermally coupled to the respective one of the integrated devices 1004. In some embodiments, a thermal interface material or another example of the layer 154 of FIG. 1 is disposed between contact(s) 1026 and the respective integrated device 1004.

In the example illustrated in FIG. 10A, the substrate 1008 also includes one or more routing traces 1018 between one or more pairs of adjacent contacts 1016. The routing traces 1018 correspond to examples of the routing traces 148 of FIG. 1. The substrate 1008 of FIG. 10A can also include a solder resist layer 1012 or another protective layer or passivation layer through which various pads and/or contacts can be accessed.

Each of the substrates 1006, 1008 can be formed using various lamination and patterning techniques. To illustrate, one or both of the substrates 1006, 1008 can be pre-formed, e.g., on a carrier, and subsequently used to form the assembly 1000. As an example, the substrate 1006 can be formed by forming a metal layer on a carrier. The metal layer can be patterned and covered with a dielectric layer. One or more vias can be formed through the dielectric layer to connect to the patterned metal layer, and another patterned metal layer can be formed on the dielectric layer. Formation of patterned metal layers, dielectric layers, and vias is repeated until all of the desired features of the substrate 1006 are formed, at which point the substrate 1006 can be removed from the carrier. Alternatively, operations, such as die attach operations to connect the integrated device(s) 1004 to the substrate 1006 can be performed before the substrate 1006 is removed from the carrier. The substrate 1008 can be formed using similar techniques to those described above.

In this example, after formation of the substrates 1006, 1008, the integrated device(s) 1004 can be attached to the substrate 1006. Conductive interconnects 1020 can also be formed on or attached to the substrate 1006. Subsequently, the substrate 1008 can be electrically connected to the conductive interconnects 1020 and thermally coupled to the integrated device(s) 1004. Optionally, a mold compound can be disposed on the substrate 1006 after the integrated device(s) 1004 are attached to the substrate 1006 or can be disposed between the substrates 1006, 1008 after the substrate 1008 is attached. In this example, formation of the assembly 1000 is complete after the substrate 1008 is attached.

Stage 2 illustrates a state after a plurality of solder balls 1030 are coupled to the contacts 1014 and 1016 of the substrate 1008. For example, the solder balls 1030 can be positioned using pick and place operations.

Stage 3 of FIG. 10B illustrates a state after integrated devices 1032 and heat slugs 1034 are attached (e.g., thermally and/or electrically connected) to the assembly 1000 by reflowing the solder balls. Each of the integrated device(s) 1032 corresponds to an example or instance of the integrated device 106 of FIG. 1. Each of the heat slugs 1034 corresponds to an example or instance of the heat slug 102 of FIG. 1. For example, each of the heat slugs 1034 includes protrusions on a surface facing the assembly 1000.

In the example illustrated, the features 1002A on the first side of the singulation line 1022 include two integrated devices 1032 (including integrated device 1032A and integrated device 1032B) electrically connected to the substrate 1008 via the solder balls 1030, and the features 1002B on the second side of the singulation line 1022 include two integrated devices 1032 (including integrated device 1032C and integrated device 1032D) electrically connected to the substrate 1008 via the solder balls 1030. In other examples, the features 1002 on each side of the singulation line 1022 include more than two or fewer than two integrated devices 1032 electrically connected to the substrate 1008 via the solder balls 1030.

Additionally, in the example illustrated, the features 1002A on the first side of the singulation line 1022 include a single heat slug 1034A thermally and, optionally electrically, connected to the substrate 1008 via the solder balls 1030, and the features 1002B on the second side of the singulation line 1022 include a single heat slug 1034B thermally and electrically connected to the substrate 1008 via the solder balls 1030. In other examples, the features 1002 on each side of the singulation line 1022 include more than one heat slug 1034 thermally and electrically connected to the substrate 1008 via the solder balls 1030.

Stage 4 illustrates a state after application of an underfill material to an upper surface of the substrate 1008. In the example illustrated, the underfill material is applied in a controlled manner on each side of the singulation line 1022 to form distinct underfill structures 1036, including an underfill structure 1036A on the first side of the singulation line 1022 and an underfill structure 1036B on the second side of the singulation line 1022. In other examples, a single underfill structure 1036 can be formed on the upper surface of the substrate 1008, or several discrete underfill structures 1036 can be formed on each side of the singulation line 1022. For example, controlled application of the underfill material can be used to form discrete underfill structures under each of the integrated devices 1032 and the heat slugs 1034.

Stage 5 of FIG. 10C illustrates a state after the assembly 1000 is cut along the singulation line to form individual packages, such as a package 1050. The state illustrated at Stage 5 is also after attachment of one or more landside passive devices 1042 to the substrate 1006 and after formation or attachment of solder balls 1040 to the off-package contacts of the package 1050.

Formation of the package 1050 is complete at Stage 5. For example, at Stage 5, the package 1050 includes one or more first integrated devices (e.g., integrated devices 1032A and 1032B) coupled to a first substrate (e.g., the substrate 1008) and one or more second integrated devices (e.g., the integrated device 1004A) coupled to a second substrate (e.g., the substrate 1006). In this example, the first substrate (e.g., the substrate 1008) is disposed between the first integrated device(s) (e.g., integrated devices 1032A and 1032B) and the second integrated device(s) (e.g., the integrated device 1004A), and the first integrated device(s) (e.g., integrated devices 1032A and 1032B) are electrically connected to the second integrated device(s) (e.g., the integrated device 1004A) by way of the conductive interconnects 1020. The package 1050 also includes one or more heat slugs (e.g., the heat slug 1034A) defining multiple protrusions, where the protrusions are thermally coupled, via contacts of the first substrate (e.g., the substrate 1008), to the second integrated device(s) (e.g., the integrated device 1004A).

FIG. 11A illustrate stages associated with operations performed at a strip level or a panel level. Thus, each Stage illustrated in FIG. 11A includes features of multiple packages. Specifically, FIG. 11A starts, at Stage 1, after formation of the assembly 1000 described with reference to FIG. 10A. As in FIG. 10A, the assembly 1000 of FIG. 11A includes features of two packages before individuation. FIGS. 11B and 11C illustrate Stages after individuation of a single package from the assembly 1000, as described further herein. The assembly 1000 of FIG. 11A includes features of two packages merely as one example. In other examples, the assembly 1000 can include features of more than two packages. In still other examples, a package can be assembled individually, in which case the assembly 1000 would include features of a single package. The assembly 1000 of FIG. 11A can be formed using the operations described with reference to Stage 1 of FIG. 10A.

Stage 2 illustrates a state after formation or attachment of solder balls 1130 to off-package contacts 1024 of the substrate 1006. The state illustrated at Stage 2 is also after attachment of one or more landside passive devices 1132 (such as landside passive devices 1132A and 1132B) to contacts of the substrate 1006.

Stage 3 of FIG. 11B illustrates a state after the assembly 1000 is cut along the singulation line 1022 (shown in FIG. 11A) to form individual package assemblies, such as a package assembly 1140.

Stage 4 illustrates a state after a plurality of solder balls 1142 are coupled to the contacts 1014 and 1016 of the substrate 1008. For example, the solder balls 1142 can be positioned using pick and place operations.

Stage 5 illustrates a state after integrated devices 1144 (e.g., integrated device 1144A and integrated device 1144B) and one or more heat slugs 1146 are attached (and electrically connected) to the package assembly 1140 by reflowing the solder balls 1142. Each of the integrated device(s) 1144 corresponds to an example or instance of the integrated device 106 of FIG. 1. Each of the heat slug(s) 1146 corresponds to an example or instance of the heat slug 102 of FIG. 1.

Stage 6 illustrates a state after application of an underfill material to an upper surface of the substrate 1008 to form an underfill structure 1148 under each of the integrated device(s) 1144 and the heat slug(s) 1146.

Formation of a package 1150 is complete at Stage 5. For example, at Stage 5, the package 1150 includes one or more first integrated devices (e.g., integrated devices 1144A and 1144B) coupled to a first substrate (e.g., the substrate 1008) and one or more second integrated devices (e.g., the integrated device 1004A) coupled to a second substrate (e.g., the substrate 1006). In this example, the first substrate (e.g., the substrate 1008) is disposed between the first integrated device(s) (e.g., integrated devices 1144A and 1144B) and the second integrated device(s) (e.g., the integrated device 1004A), and the first integrated device(s) (e.g., integrated devices 1144A and 1144B) are electrically connected to the second integrated device(s) (e.g., the integrated device 1004A) by way of the conductive interconnects 1020. The package 1150 also includes one or more heat slugs (e.g., the heat slug 1146) defining multiple protrusions, where the protrusions are thermally coupled, via contacts of the first substrate (e.g., the substrate 1008), to the second integrated device(s) (e.g., the integrated device 1004A).

### Exemplary Flow Diagram of a Method for Fabricating a Package Including Substrates, Integrated Devices and a Heat Slug

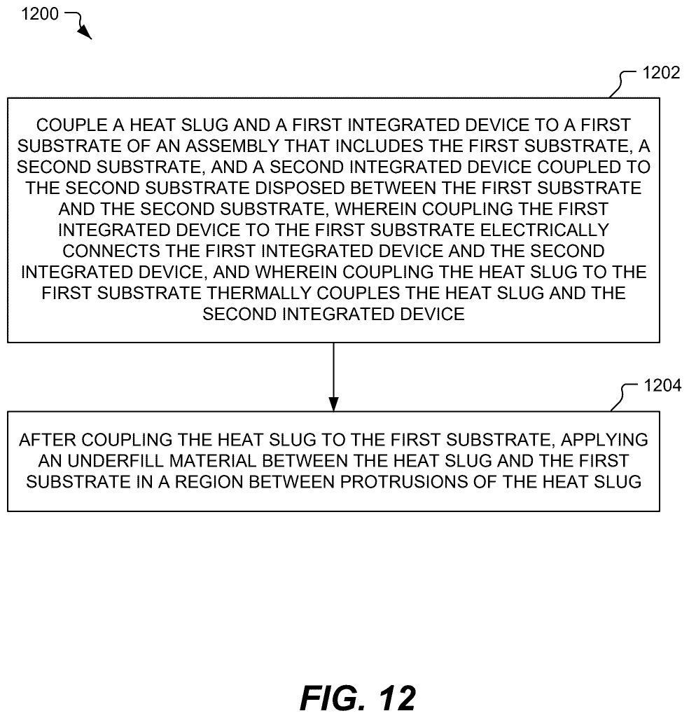

In some implementations, fabricating a package that includes substrates, integrated devices, and one or more heat slugs includes several processes. FIG. 12 illustrates an exemplary flow diagram of a method 1200 of fabricating an illustrative package that includes substrates, integrated devices, and one or more heat slugs. In a particular aspect, one or more operations of the method 1200 are initiated, performed, or controlled by one or more processors of a fabrication system. In some implementations, operations of the method 1200 may be stored as instructions by a non-transitory computer-readable storage medium, and the instructions may be executable by at least one processor to cause the at least one processor to perform operations of the method 1200. In some implementations, the method 1200 of FIG. 12 may be used to provide or fabricate the package 190 of any of FIGS. 1-4, which can include any of the configurations described with reference to FIGS. 5-9, the package 1050 of FIG. 10C, or the package 1150 of FIG. 11C.

It should be noted that the method 1200 of FIG. 12 may combine one or more processes in order to simplify and/or clarify the method for providing or fabricating an integrated circuit device. In some implementations, the order of the processes may be changed or modified. In some implementations, one or more operations of the method 1200 correspond to, include, or are combined with one or more operations as described with references to FIG. 10A-10C or 11A-11C.

The method 1200 includes, at block 1202, coupling a heat slug and a first integrated device to a first substrate of an assembly. The assembly includes the first substrate, a second substrate, and a second integrated device coupled to the second substrate disposed between the first substrate and the second substrate. For example, the assembly can include or correspond to the assembly 1000 of FIG. 10A, which includes the substrate 1008 (e.g., a first substrate), the substrate 1006 (e.g., a second substrate), and one or more integrated devices 1004 (e.g., a second integrated device) coupled to the substrate 1006 (e.g., the second substrate) disposed between the substrate 1008 (e.g., the first substrate) and the substrate 1006 (e.g., the second substrate). The first integrated device, the second integrated device, or both, can include or correspond to stacked dies.

In a particular aspect, coupling the first integrated device to the first substrate electrically connects the first integrated device and the second integrated device, and coupling the heat slug to the first substrate thermally couples the heat slug and the second integrated device. For example, in FIG. 10C, the integrated device(s) 1032 are electrically connected to the integrated device 1004A via the substrate 1008, the conductive interconnects 1020, and the substrate 1006. Further, in FIG. 10C, the heat slug 1034A is thermally coupled to the integrated device 1004A by vias extending through the substrate 1008. In some embodiments, the heat slug and the first integrated device are coupled to a first substrate concurrently using a single solder reflow operation. In other embodiments, the heat slug and the first integrated device are coupled to a first substrate sequentially using two or more solder reflow operations.

In some embodiments, the heat slug includes a unitary mass of metal that is formed or manipulated to include multiple protrusions arranged in rows and columns to define an array of protrusions. The heat slug can be coupled to the first substrate by reflowing solder to connect protrusions of the heat slug to contacts of the first substrate. In some embodiments, coupling the heat slug to the first substrate also electrically connects the heat slug to a ground of the first substrate. The heat slug can be coupled to the first substrate at a location that is configured to enable positioning of the first integrated device (and optionally one or more additional integrated devices) and to permit sufficient heat flow between the second integrated device and the heat slug. For example, the heat slug may be coupled to the first substrate at a location such that at least part of the heat slug vertically overlaps with at least part of the second integrated device. In other examples, the heat slug can be vertically offset from the second integrated device.

The method 1200 includes, at block 1204, after coupling the heat slug to the first substrate, applying an underfill material between the heat slug and the first substrate in a region between protrusions of the heat slug. For example, at Stage 4 of FIG. 10B, the underfill material is applied to form the underfill structure 1036A between the heat slug 1034A and the substrate 1008 (e.g., the first substrate) in a region between protrusions of the heat slug 1034A. In some embodiments, the protrusions of the heat slug are spaced apart from one another at a distance that is selected to enable even distribution of the underfill material.

In some embodiments, the method 1200 also includes coupling protrusions of one or more additional heat slugs to the first substrate. To illustrate, during formation of a package having the configuration illustrated in the example of FIG. 8 or FIG. 9, the heat slug 102A can correspond to a first heat slug and the heat slug 102B can correspond to a second heat slug of the one or more additional heat slugs thermally couple the first substrate. Although FIGS. 8 and 9 illustrate examples that include two heat slugs 102, in other examples, a package can include more than two heat slugs 102.

In some embodiments, the method 1200 also includes coupling one or more third integrated device to the first substrate and electrically connected to the first integrated device, the second integrated device, or both. To illustrate, in the example illustrated in FIG. 10C, an integrated device 1032A and one or more additional integrated devices (e.g., integrated device 1032B) corresponding to one or more third integrated device are coupled to the substrate 1008 (e.g., the first substrate) and electrically connected to the integrated device 1032A (e.g., the first integrated device), to the integrated device 1004A (e.g., the second integrated device), or both. In some such embodiments, the heat slug is coupled to the first substrate at a location between the first integrated device and at least one of the one or more third integrated devices. For example, the heat slug 1034A of FIG. 10C is coupled to the substrate 1008 (e.g., the first substrate) at a location between the integrated device 1032A (e.g., the first integrated device) and the integrated device 1032B (e.g., one of the one or more third integrated devices).

In some embodiments, the method 1200 also includes coupling one or more surface mounted passive devices to the first substrate, the second substrate, or both. For example, during formation of the package 190 of FIG. 3, one or more of the passive devices 302 can be coupled to the substrate 108, to the substrate 110, or both.

### Exemplary Electronic Devices

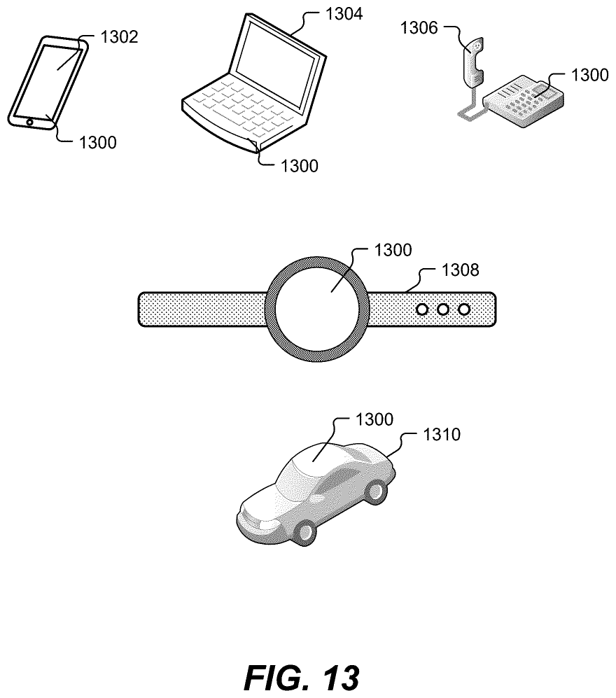

FIG. 13 illustrates various electronic devices that may include or be integrated with any of the packages described above. For example, a mobile phone device 1302, a laptop computer device 1304, a fixed location terminal device 1306, a wearable device 1308, or a vehicle 1310 (e.g., an automobile or an aerial device) may include a device 1300. The device 1300 can include, for example, the package 190 of any of FIGS. 1-4, which can include any of the configurations described with reference to FIGS. 5-9, the package 1050 of FIG. 10C, or the package 1150 of FIG. 11C. The devices 1302, 1304, 1306 and 1308 and the vehicle 1310 illustrated in FIG. 13 are merely exemplary. Other electronic devices may also feature the device 1300 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1-13 may be rearranged and/or combined into a single component, process, feature or function or embodied in several components, processes, or functions. Additional elements, components, processes, and/or functions may also be added without departing from the disclosure. It should also be noted FIGS. 1-13 and its corresponding description in the present disclosure is not limited to dies and/or ICs. In some implementations, FIGS. 1-13 and the corresponding descriptions may be used to manufacture, create, provide, and/or produce devices and/or integrated devices. In some implementations, a device may include a die, an integrated device, an embedded multi-chip package, an integrated passive device (IPD), a die package, an IC device, a device package, an IC package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first,” “second,” “third,” and “fourth” (and/or anything above fourth) is arbitrary. Any of the components described may be the first component, the second component, the third component or the fourth component. For example, a component that is referred to as a second component, may be the first component, the second component, the third component or the fourth component. The terms “encapsulate,” “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various aspects contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a device includes a first integrated device coupled to a first substrate; a second integrated device coupled to a second substrate, wherein the first substrate is disposed between the first integrated device and the second integrated device and the first integrated device is electrically connected to the second integrated device; and a heat slug defining multiple protrusions, wherein the protrusions are thermally coupled, via contacts of the first substrate, to the second integrated device.

Example 2 includes the device of Example 1, wherein the protrusions are coupled to the contacts of the first substrate using solder.

Example 3 includes the device of Example 1 or Example 2, wherein the protrusions are arranged in rows and columns to define an array of protrusions.

Example 4 includes the device of any of Examples 1 to 3, wherein the heat slug includes a unitary mass of metal.

Example 5 includes the device of any of Examples 1 to 4 and further includes at least one additional heat slug defining additional protrusions, wherein the additional protrusions are thermally coupled, via additional contacts of the first substrate, to the second integrated device.

Example 6 includes the device of any of Examples 1 to 5 and further includes one or more third integrated devices coupled to the first substrate and electrically connected to the first integrated device, the second integrated device, or both.

Example 7 includes the device of Example 6, wherein the heat slug is disposed between the first integrated device and at least one of the one or more third integrated devices.

Example 8 includes the device of any of Examples 1 to 7, wherein the first substrate includes one or more routing traces between a pair of adjacent contacts of the first substrate.

Example 9 includes the device of any of Examples 1 to 8, one or more of the contacts of the first substrate couple the heat slug to a ground of the first substrate.

Example 10 includes the device of any of Examples 1 to 9 and further includes underfill material disposed between the heat slug and the first substrate in a region between two or more of the protrusions.

Example 11 includes the device of Example 10, wherein the protrusions are spaced apart from one another at a distance configured to facilitate even distribution of the underfill material.

Example 12 includes the device of any of Examples 1 to 11, wherein at least part of the heat slug vertically overlaps with at least part of the second integrated device.

Example 13 includes the device of any of Examples 1 to 12, wherein the first substrate includes a plurality of through substrate vias between the heat slug and the second integrated device.

Example 14 includes the device of any of Examples 1 to 13 and further includes a plurality of interconnects electrically connecting the first substrate and the second substrate and configured to provide conductive paths between the first integrated device and the second integrated device.

Example 15 includes the device of any of Examples 1 to 14, wherein the first integrated device, the second integrated device, or both, include stacked dies.

Example 16 includes the device of any of Examples 1 to 15 and further includes one or more surface mounted passive devices coupled to the first substrate, the second substrate, or both.

According to Example 17, a method of fabrication includes coupling a heat slug and a first integrated device to a first substrate of an assembly. The assembly includes the first substrate, a second substrate, and a second integrated device coupled to the second substrate disposed between the first substrate and the second substrate. Coupling the first integrated device to the first substrate electrically connects the first integrated device and the second integrated device, and coupling the heat slug to the first substrate thermally couples the heat slug and the second integrated device. The method also includes, after coupling the heat slug to the first substrate, applying an underfill material between the heat slug and the first substrate in a region between protrusions of the heat slug.

Example 18 includes the method of Example 17, wherein coupling the heat slug to the first substrate comprises reflowing solder to connect protrusions of the heat slug to contacts of the first substrate.

Example 19 includes the method of Example 17 or Example 18, wherein the heat slug defines multiple protrusions arranged in rows and columns to define an array of protrusions.

Example 20 includes the method of Example 18, wherein the protrusions are spaced apart from one another at a distance configured to facilitate even distribution of the underfill material.

Example 21 includes the method of any of Examples 17 to 20, wherein the heat slug comprises a unitary mass of metal.

Example 22 includes the method of any of Examples 17 to 21 and further includes coupling protrusions of one or more additional heat slugs to the first substrate, wherein coupling the protrusions of the one or more additional heat slugs to the first substrate thermally couples the one or more additional heat slugs and the second integrated device.

Example 23 includes the method of any of Examples 17 to 22 and further includes coupling one or more third integrated devices to the first substrate and electrically connected to the first integrated device, the second integrated device, or both.

Example 24 includes the method of Example 23, wherein the heat slug is coupled to the first substrate at a location between the first integrated device and at least one of the one or more third integrated devices.

Example 25 includes the method of any of Examples 17 to 24 and further includes coupling one or more surface mounted passive devices to the first substrate, the second substrate, or both.

Example 26 includes the method of any of Examples 17 to 25, wherein coupling the heat slug to the first substrate electrically connects the heat slug to a ground of the first substrate.

Example 27 includes the method of any of Examples 17 to 26, wherein the heat slug is coupled to the first substrate at a location such that at least part of the heat slug vertically overlaps with at least part of the second integrated device.

Example 28 includes the method of any of Examples 17 to 27, wherein the first integrated device, the second integrated device, or both, comprise stacked dies.

Example 29 includes the method of any of Examples 17 to 28, wherein coupling the heat slug and the first integrated device to the first substrate includes performing a solder reflow operation that concurrently couples the heat slug and the first integrated device to the first substrate.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A device comprising:
a first integrated device coupled to a first substrate;
a second integrated device coupled to a second substrate, wherein the first substrate is disposed between the first integrated device and the second integrated device and the first integrated device is electrically connected to the second integrated device; and
a heat slug defining protrusions, wherein the protrusions are thermally coupled, via contacts of the first substrate, to the second integrated device.

2. The device of claim 1, wherein the protrusions are coupled to the contacts of the first substrate using solder.

3. The device of claim 1, wherein the protrusions are arranged in rows and columns to define an array of protrusions.

4. The device of claim 1, wherein the heat slug comprises a unitary mass of metal.

5. The device of claim 1, further comprising at least one additional heat slug defining additional protrusions, wherein the additional protrusions are thermally coupled, via additional contacts of the first substrate, to the second integrated device.

6. The device of claim 1, further comprising one or more third integrated devices coupled to the first substrate and electrically connected to the first integrated device, the second integrated device, or both, and wherein the heat slug is disposed between the first integrated device and at least one of the one or more third integrated devices.

7. The device of claim 1, wherein the first substrate includes one or more routing traces between a pair of adjacent contacts of the first substrate.

8. The device of claim 1, wherein one or more of the contacts of the first substrate couple the heat slug to a ground of the first substrate.

9. The device of claim 1, further comprising underfill material disposed between the heat slug and the first substrate in a region between two or more of the protrusions, and wherein the protrusions are spaced apart from one another at a distance configured to facilitate even distribution of the underfill material.

10. The device of claim 1, wherein the first substrate includes a plurality of through substrate vias between the heat slug and the second integrated device.

11. The device of claim 1, wherein the first integrated device, the second integrated device, or both, comprise stacked dies.

12. The device of claim 1, further comprising one or more surface mounted passive devices coupled to the first substrate, the second substrate, or both.

13. A method of fabrication comprising:
coupling a heat slug and a first integrated device to a first substrate of an assembly that includes:
the first substrate,
a second substrate, and
a second integrated device coupled to the second substrate, and disposed between the first substrate and the second substrate,
wherein coupling the first integrated device to the first substrate electrically connects the first integrated device and the second integrated device, and wherein coupling the heat slug to the first substrate thermally couples the heat slug and the second integrated device; and
after coupling the heat slug to the first substrate, applying an underfill material between the heat slug and the first substrate in a region between protrusions of the heat slug.

14. The method of claim 13, wherein the heat slug defines the protrusions arranged in rows and columns to define an array of protrusions, and wherein the protrusions are spaced apart from one another at a distance configured to facilitate even distribution of the underfill material.

15. The method of claim 13, further comprising coupling protrusions of one or more additional heat slugs to the first substrate, wherein coupling the protrusions of the one or more additional heat slugs to the first substrate thermally couples the one or more additional heat slugs and the second integrated device.

16. The method of claim 13, further comprising coupling one or more third integrated devices to the first substrate and electrically connected to the first integrated device, the second integrated device, or both, and wherein the heat slug is coupled to the first substrate at a location between the first integrated device and at least one of the one or more third integrated devices.

17. The method of claim 13, further comprising coupling one or more surface mounted passive devices to the first substrate, the second substrate, or both.

18. The method of claim 17, wherein coupling the heat slug to the first substrate electrically connects the heat slug to a ground of the first substrate.

19. The method of claim 17, wherein the heat slug is coupled to the first substrate at a location such that at least part of the heat slug vertically overlaps with at least part of the second integrated device.

20. The method of claim 17, wherein coupling the heat slug and the first integrated device to the first substrate includes performing a solder reflow operation that concurrently couples the heat slug and the first integrated device to the first substrate.
